(19) United States
(12) Patent Application Publication
(10) Pub. No.: US 2025/0386549 A1
(43) Pub. Date: Dec. 18, 2025

(54) SEMICONDUCTOR DEVICE AND MANUFACTURING METHOD THEREOF

(71) Applicant: Taiwan Semiconductor Manufacturing Company, Ltd., Hsinchu (TW)

(72) Inventors: Pei-Yu WANG, Hsinchu (TW); Shih-Cheng CHEN, Hsinchu (TW); Wen-Ting LAN, Hsinchu (TW); Jia-Chuan YOU, Hsinchu (TW)

(73) Assignee: Taiwan Semiconductor Manufacturing Company, Ltd., Hsinchu (TW)

(21) Appl. No.: 18/746,465

(22) Filed: Jun. 18, 2024

(51) Int. Cl. H01L 29/423; H01L 21/8234; H01L 27/088; H01L 29/06; H01L 29/08; H01L 29/66; H01L 29/775; H01L 29/786

(52) U.S. Cl. CPC H10D 30/6735; H10D 30/014; H10D 30/43; H10D 30/6757; H10D 62/121; H10D 62/151; H10D 64/017; H10D 64/018; H10D 84/0128; H10D 84/013; H10D 84/038; H10D 84/83

(57) ABSTRACT

A method of manufacturing a semiconductor device is provided. A sacrificial layer and a fin structure covering the sacrificial layer and having a plurality of first semiconductor layers and a plurality of second semiconductor layers alternately stacked are formed on a substrate. Edge portions of the second semiconductor layers are removed to form cavities between the first semiconductor layers. A dielectric spacer is formed on sidewalls of the second semiconductor layers and fills the cavities. A bottom portion of the fin structure that covers the sacrificial layer is etched to expose the sacrificial layer. An epitaxial source/drain feature is formed such that a side surface of the epitaxial source/drain feature contacts the first semiconductor layers and the dielectric spacers, and a bottom surface of the epitaxial source/drain feature contact the sacrificial layer. The sacrificial layer is removed to form a gap between the epitaxial source/drain feature and the substrate.

### BACKGROUND

The electronics industry has a growing demand for smaller and faster electronic devices that can simultaneously support a greater number of increasingly complex functions. Accordingly, there is a continuing trend in the semiconductor industry to manufacture low cost, high performance and low power integrated circuits (ICs). So far, these goals have been achieved largely by reducing IC dimensions (e.g., minimum feature size) of a semiconductor to increase production efficiency and reduce associated manufacture costs. However, this technique of reducing the IC dimensions of the semiconductor also increases the complexity of the semiconductor manufacturing process. Therefore, in order to cope with the continuous improvement and IC technologies of semiconductor, the semiconductor manufacturing processes and related technologies also need to be improved.

Recently, multi-gate devices have been introduced into fin field-effect transistors (FinFETs). FinFETs have been used in various applications, for example, to implement logic devices/circuits or the like. Generally speaking, logic devices may focus on electrical performance (e.g., threshold voltage, saturation current, and breakdown voltage etc.). However, optimization of the performance and/or design requirements of FinFET devices has been challenging.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-6 are perspective views of various stages of manufacturing a semiconductor device in accordance with some embodiments.

FIGS. 7A and 7B are cross-sectional views of the semiconductor device taken along line A-A and line B-B of FIG. 6, respectively.

FIGS. 8A-8D are cross-sectional views of the semiconductor device taken along line A-A of FIG. 6, showing various stages of manufacturing the semiconductor device in accordance with some embodiments.

FIGS. 9A-14A are cross-sectional views of various stages of manufacturing the semiconductor device taken along cross-section A-A of FIG. 6, in accordance with some embodiments.

FIGS. 9B-14B are cross-sectional views of various stages of manufacturing the semiconductor device taken along cross-section B-B of FIG. 6, in accordance with some embodiments.

FIGS. 12C-12D are cross-sectional views of removing the sacrificial gate structure and the second semiconductor layers in accordance with some embodiments.

FIGS. 15A-15F are schematic diagrams illustrating a method for removing a sacrificial layer in accordance with some embodiments.

FIGS. 16A-16C are schematic diagrams illustrating a method for removing a sacrificial layer in accordance with some embodiments.

FIGS. 17A-17C are schematic diagrams illustrating a semiconductor device having different type of internal connection channel in accordance with some embodiments.

FIG. 18 is another schematic diagram illustrating a semiconductor device in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

While the embodiments of this disclosure are discussed with respect to nanostructure channel FETs (e.g. Horizontal Gate All Around (HGAA) FETs, Vertical Gate All Around (VGAA) FETs, nanosheet/nanowire FET, nano-ribbon FET, Multi-Bridge-Channel FET), implementations of some aspects of the present disclosure may be used in other processes and/or in other devices, such as planar FETs, Fin-FETs, and other suitable devices. A person having ordinary skill in the art will readily understand other modifications that may be made are contemplated within the scope of this disclosure.

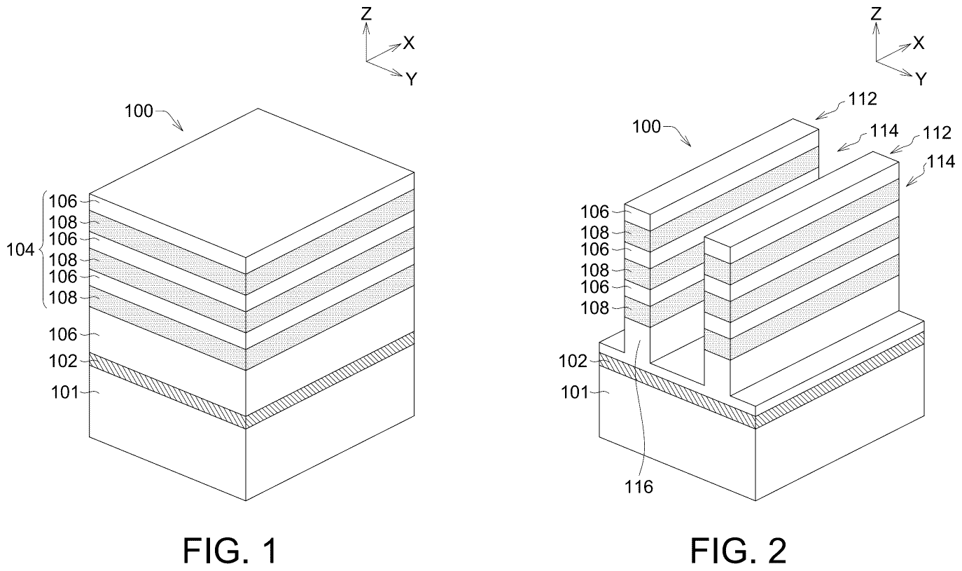

FIGS. 1-14B show exemplary processes for manufacturing a semiconductor device 100 according to embodiments of the present disclosure. It is understood that additional operations can be provided before, during, and after processes shown by FIGS. 1-14B, and some of the operations described below can be replaced or eliminated, for additional embodiments of the method. The order of the operations/processes is not limiting and may be interchangeable.

FIGS. 1-6 are perspective views of various stages of manufacturing a semiconductor device 100 in accordance with some embodiments. As shown in FIG. 1, a semiconductor device 100 includes a stack of semiconductor layers 104 and a sacrificial layer 102 formed over a substrate 101. The substrate 101 may be a semiconductor substrate. The substrate 101 may include a single crystalline semiconductor material such as, but not limited to silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb) and indium phosphide (InP). In some embodiments, the substrate 101 is a silicon-on-insulator (SOI) substrate having an insulating layer (not shown) disposed between two silicon layers for enhancement. In one aspect, the insulating layer is an oxygen-containing layer.

The substrate 101 may include various regions that have been doped with impurities (e.g., dopants having p-type or n-type conductivity). Depending on circuit design, the dopants may be, for example boron for p-type field effect transistors (PFET) and phosphorus for n-type field effect transistors (NFET).

The stack of semiconductor layers 104 includes semiconductor layers made of different materials to facilitate formation of nanostructure channels in a multi-gate device, such as nanostructure FETs. In some embodiments, the stack of semiconductor layers 104 includes first semiconductor layers 106 and second semiconductor layers 108. In some embodiments, the stack of semiconductor layers 104 includes alternating first and second semiconductor layers 106, 108, and the first and second semiconductor layers 106, 108 are disposed in parallel with each other. The first semiconductor layers 106 and the second semiconductor layers 108 are made of semiconductor materials having different etch selectivity and/or oxidation rates. For example, the first semiconductor layers 106 may be made of Si and the second semiconductor layers 108 may be made of SiGe. In some examples, the first semiconductor layers 106 may be made of Si doped with Ge and the second semiconductor layers 108 may be made of SiGe. In some examples, the first semiconductor layers 106 may be made of SiGe and the second semiconductor layers 108 may be made of Si. In some embodiments, the first semiconductor layers 106 may be made of SiGe having a first Ge concentration range, and the second semiconductor layers 108 may be made of SiGe having a second Ge concentration range that is lower or greater than the first Ge concentration range. Alternatively, in some embodiments, either of the semiconductor layers 106, 108 may be or include other materials such as Ge, SiC, GeAs, GaP, InP, InAs, InSb, GaAsP, AlInAs, AlGaAs, InGaAs, GaInP, GaInAsP, or any combinations thereof.

The thickness of the first semiconductor layers 106 and the second semiconductor layers 108 may vary depending on the application and/or device performance considerations. In some embodiments, each first and second semiconductor layer 106, 108 has a thickness in a range between about 5 nm and about 30 nm. In other embodiments, each first and second semiconductor layer 106, 108 has a thickness in a range between about 10 nm and about 20 nm. In some embodiments, each first and second semiconductor layer 106, 108 has a thickness in a range between about 6 nm and about 12 nm. Each second semiconductor layer 108 may have a thickness that is equal to, less than, or greater than the thickness of the first semiconductor layer 106. The second semiconductor layers 108 may eventually be removed and serve to define a vertical distance between adjacent channels for the semiconductor device 100.

The sacrificial layer 102 is located below the stack of semiconductor layers 104. The sacrificial layer 102 is first formed on the substrate 101, and then the first semiconductor layer 106 and the second semiconductor layer 108 are sequentially formed and stacked on the sacrificial layer 102. The sacrificial layer 102 may be made of a semiconductor material that has the same etch selectivity and/or oxidation rate as the second semiconductor layer 108, such as Ge, SiGe, SiC, GeAs, GaP, InP, InAs, InSb, GaAsP, AlInAs, AlGaAs, InGaAs, GaInP, GaInAsP or any combination thereof. The sacrificial layer 102 can be partially or completely removed at a later manufacturing stage to form a cavity (or gap).

The first semiconductor layers 106 or portions thereof may form nanostructure channel(s) of the semiconductor device 100 in later fabrication stages. The term nanostructure is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including, for example, a cylindrical in shape or substantially rectangular cross-section. The nanostructure channel(s) of the semiconductor device 100 may be surrounded by a gate electrode. The semiconductor device 100 may include a nanostructure transistor. The nanostructure transistors may be referred to as nanowire transistors, gate-all-around (GAA) transistors, multi-bridge channel (MBC) transistors, or any transistors having the gate electrode surrounding the channels. The use of the first semiconductor layers 106 to define a channel or channels of the semiconductor device 100 is further discussed below.

The first and second semiconductor layers 106, 108 are formed by any suitable deposition process, such as epitaxy. By way of example, epitaxial growth of the layers of the stack of semiconductor layers 104 may be performed by a molecular beam epitaxy (MBE) process, a metalorganic chemical vapor deposition (MOCVD) process, and/or other suitable epitaxial growth processes. While three first semiconductor layers 106 and three second semiconductor layers 108 are alternately arranged as illustrated in FIG. 1, it can be appreciated that any number of first and second semiconductor layers 106, 108 can be formed in the stack of semiconductor layers 104, depending on the predetermined number of nanostructure channels for each FET. For example, the number of first semiconductor layers 106, which is the number of channels, may be between 2 and 8.

In FIG. 2, fin structures 112 are formed from the stack of semiconductor layers 104. Each of the fin structures 112 has an upper portion including the semiconductor layers 106, 108 and a well portion 116 formed from the substrate 101. The fin structures 112 may be formed by patterning a hard mask layer (not shown) formed on the stack of semiconductor layers 104 using multi-patterning operations including photo-lithography and etching processes. The etching process can include dry etching, wet etching, reactive ion etching (RIE), and/or other suitable processes. The photo-lithography process may include forming a photoresist layer (not shown) over the hard mask layer, exposing the photoresist layer to a pattern, performing post-exposure bake processes, and developing the photoresist layer to form a masking element including the photoresist layer. In some embodiments, patterning the photoresist layer to form the masking element may be performed using an electron beam (e-beam) lithography process. The etching process forms trenches 114 in unprotected regions through the hard mask layer, through the stack of semiconductor layers 104, and into the substrate 101, thereby leaving the plurality of extending fin structures 112. The trenches 114 extend along the X direction. The trenches 114 may be etched using a dry etch (e.g., RIE), a wet etch, and/or combination thereof.

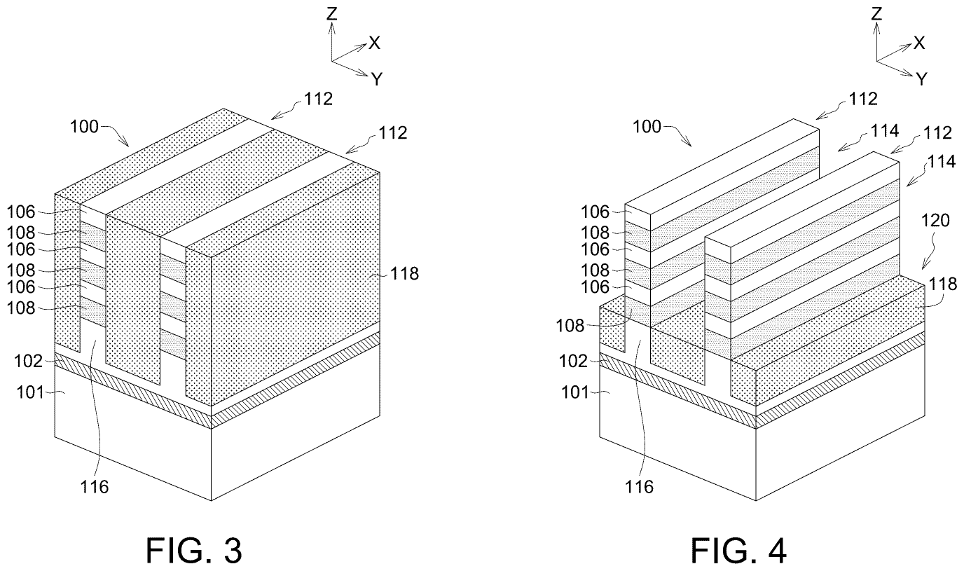

In FIG. 3, after the fin structures 112 are formed, an insulating material 118 is formed on the substrate 101. The insulating material 118 fills the trenches 114 (FIG. 2) between neighboring fin structures 112 until the fin structures 112 are embedded in the insulating material 118. Then, a planarization operation, such as a chemical mechanical polishing (CMP) method and/or an etch-back method, is performed such that the top of the fin structures 112 is exposed. The insulating material 118 may be made of silicon oxide, silicon nitride, silicon oxynitride (SiON), SiOCN, SiCN, fluorine-doped silicate glass (FSG), a low-K dielectric material, or any suitable dielectric material. The insulating material 118 may be formed by any suitable method, such as low-pressure chemical vapor deposition (LPCVD), plasma enhanced CVD (PECVD) or flowable CVD (FCVD).

In FIG. 4, the insulating material 118 is recessed to form an isolation region 120. The recess of the insulating material 118 exposes portions of the fin structures 112, such as the stack of semiconductor layers 104. The recess of the insulating material 118 reveals the trenches 114 between the neighboring fin structures 112. The isolation region 120 may be formed using a suitable process, such as a dry etching process, a wet etching process, or a combination thereof. A top surface of the insulating material 118 may be level with or below a surface of the second semiconductor layers 108 in contact with the well portion 116 formed from the substrate 101.

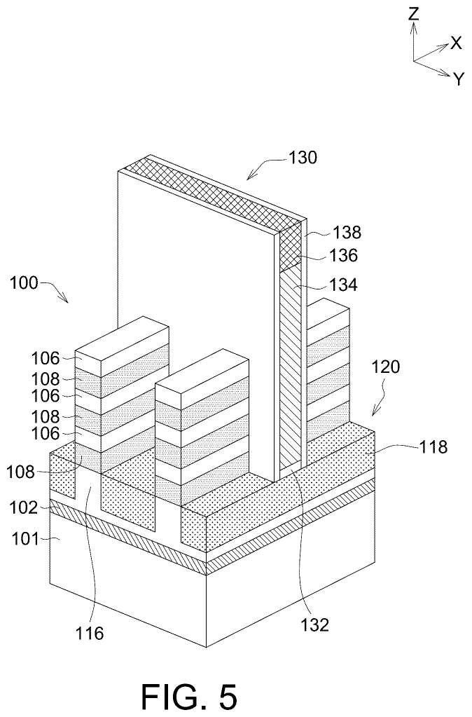

In FIG. 5, one or more sacrificial gate structures 130 are formed over the semiconductor device 100. The sacrificial gate structures 130 are formed over a portion of the fin structures 112. Each sacrificial gate structure 130 may include a sacrificial gate dielectric layer 132, a sacrificial gate electrode layer 134, and a mask layer 136. The sacrificial gate dielectric layer 132, the sacrificial gate electrode layer 134, and the mask layer 136 may be formed by sequentially depositing blanket layers of the sacrificial gate dielectric layer 132, the sacrificial gate electrode layer 134, and the mask layer 136, and then patterning those layers into the sacrificial gate structures 130. Gate spacers 138 are then formed on sidewalls of the sacrificial gate structures 130. The gate spacers 138 may be formed by conformally depositing one or more layers for the gate spacers 138 and anisotropically etching the one or more layers, for example. While one sacrificial gate structure 130 is shown, two or more sacrificial gate structures 130 may be arranged along the X direction in some embodiments.

The sacrificial gate dielectric layer 132 may include one or more layers of dielectric material, such as a silicon oxide-based material. The sacrificial gate electrode layer 134 may include silicon such as polycrystalline silicon or amorphous silicon. The mask layer 136 may include more than one layer, such as an oxide layer and a nitride layer. The gate spacer 138 may be made of a dielectric material such as silicon oxide, silicon nitride, silicon carbide, silicon oxynitride, SiCN, silicon oxycarbide, SiOCN, and/or combinations thereof.

The portions of the fin structures 112 that are covered by the sacrificial gate electrode layer 134 of the sacrificial gate structure 130 serve as channel regions for the semiconductor device 100. The fin structures 112 that are partially exposed on opposite sides of the sacrificial gate structure 130 define source/drain (S/D) regions 105, 107 for the semiconductor device 100. In some cases, some S/D regions may be shared between various transistors. For example, various one of the S/D regions may be connected together and implemented as multiple functional transistors.

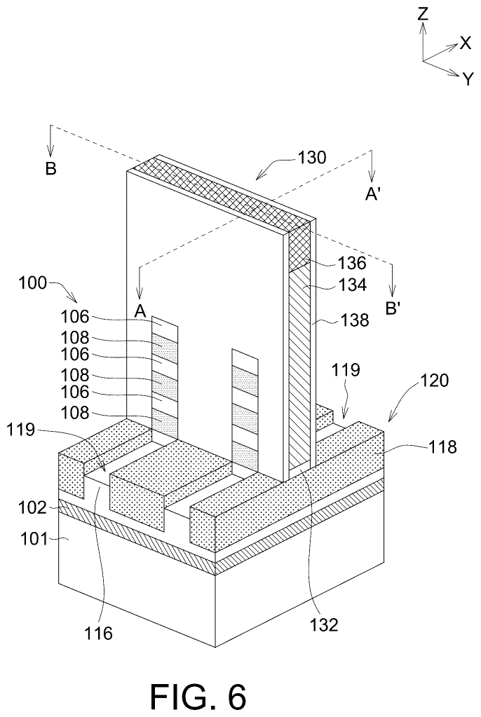

In FIG. 6, the portions of the fin structures 112 in the S/D regions (e.g., regions on opposite sides of the sacrificial gate structure 130) are recessed down below the top surface of the isolation region 120 (or the insulating material 118), by removing portions of the fin structures 112 not covered by the sacrificial gate structure 130. The recess of the portions of the fin structures 112 can be done by an etch process, either isotropic or anisotropic etch process, or further, may be selective with respect to one or more crystalline planes of the substrate 101. The etch process may be a dry etch, such as a RIE, NBE, or the like, or a wet etch, such as using tetramethyalammonium hydroxide (TMAH), ammonium hydroxide (NH₄OH), or any suitable etchant. Trenches 119 are formed in the S/D regions as the result of the recess of the portions of the fin structures 112.

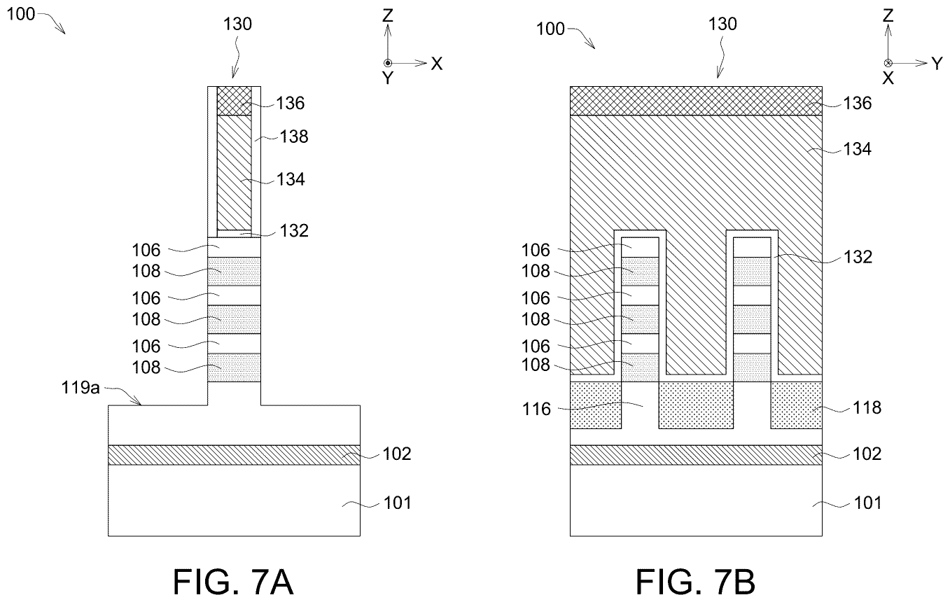

FIGS. 7A and 7B are cross-sectional views of the semiconductor device 100 taken along line A-A and line B-B of FIG. 6, respectively. Cross-section A-A is in a plane of the fin structure 112 along the X direction. Cross-section B-B is in a plane perpendicular to cross-section A-A and is in the sacrificial gate structure 130.

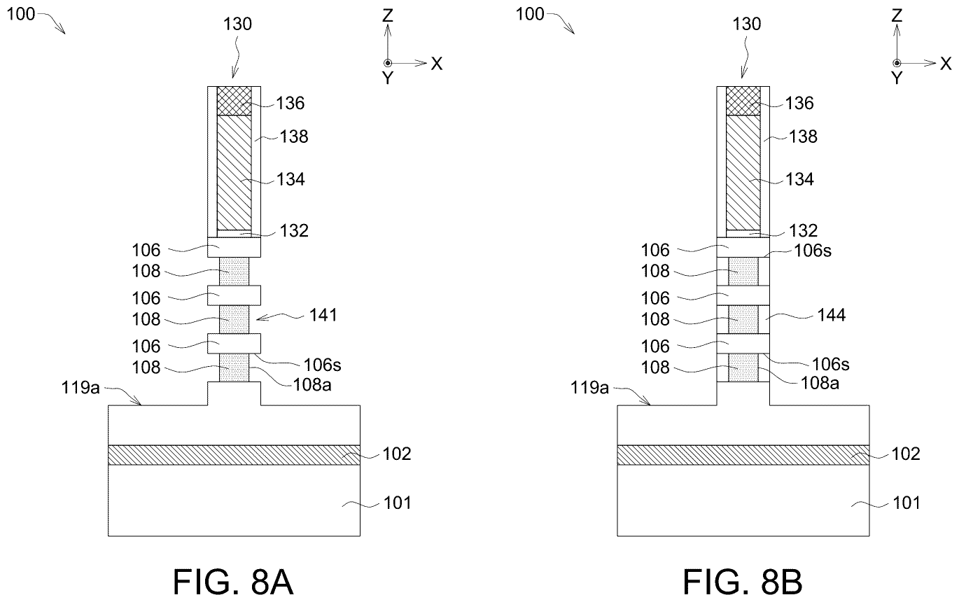

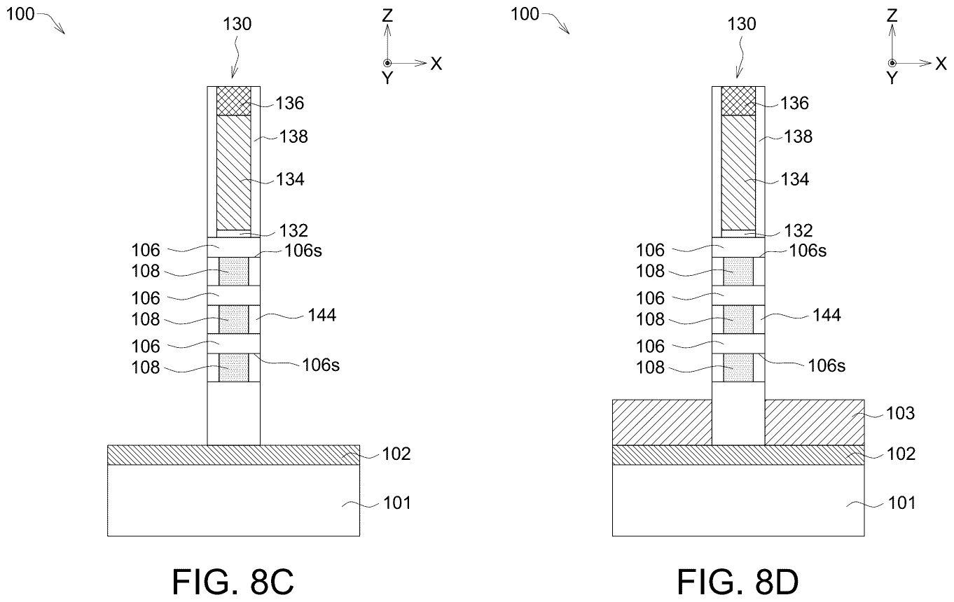

FIGS. 8A-8D are cross-sectional views of the semiconductor device 100 taken along line A-A of FIG. 6, showing various stages of manufacturing the semiconductor device 100 in accordance with some embodiments. In FIG. 8A, edge portions of each second semiconductor layer 108 of the stack of semiconductor layers 104 are removed horizontally along the X direction. The removal of the edge portions of the second semiconductor layers 108 forms cavities 141. In some embodiments, the portions of the second semiconductor layers 108 are removed by a selective wet etching process. In cases where the second semiconductor layers 108 are made of SiGe and the first semiconductor layers 106 are made of silicon, the second semiconductor layer 108 can be selectively etched using a wet etchant such as, but not limited to, ammonium hydroxide (NH₄OH), tetramethylammonium hydroxide (TMAH), ethylenediamine pyrocatechol (EDP), or potassium hydroxide (KOH) solutions. The removal of edge portions of the second semiconductor layers 108 expose a portion of first side surfaces 106s of the first semiconductor layers 106 along the X direction.

In FIG. 8B, after removing the edge portion of the second semiconductor layer 108, a dielectric layer is deposited in the cavities 141 (FIG. 8A) to form dielectric spacers (or so-called inner spacers) 144. The dielectric spacers 144 may be made of a low-k dielectric material, such as SiON, SiCN, SiOC, SiOCN, or SiN. In some embodiments, the dielectric spacers 144 are formed of a material have a k value in a range of 3.5 to 5.5. The dielectric spacers 144 may be formed by ALD, pulsed plasma CVD, or any suitable deposition process. The remaining second semiconductor layers 108 are capped between the dielectric spacers 144 along the X direction.

In FIG. 8B, end portions of the dielectric spacers 144 under the first semiconductor layers 106 may have flat surfaces which are substantially flush with the outer surface of the first semiconductor layers 106, as shown in FIG. 8B.

In FIG. 8C, the bottom portion 119 of the source/drain regions 105, 107 covering the sacrificial layer 102 is removed, such as by etching. The etching process may be wet etching, such as using tetramethylammonium hydroxide (TMAH), ammonium hydroxide (NH₄OH) or any suitable etchant. Then, the sacrificial layer 102 is exposed in the source/drain regions 105, 107. In FIG. 8D, an elevated layer 103 of the same material as the sacrificial layer 102 may be further deposited or refilled above the sacrificial layer 102. The top surface of the elevated layer 103 may be flush with or lower than the top surface of the well portion 116. In subsequent processes, the height of the top surface of the elevated layer 103 may determine the height of the gap 105a between the epitaxial S/D features 146 and the substrate 101 to reduce the contact area between the epitaxial S/D features 146 and the substrate 101 and the induced leakage current. In another embodiment, another insulating material (not shown) can be additionally formed under the epitaxial S/D features 146 to reduce the contact area between the epitaxial S/D features 146 and the substrate 101 and the induced leakage current without adding an elevated layer 103 above the sacrificial layer 102.

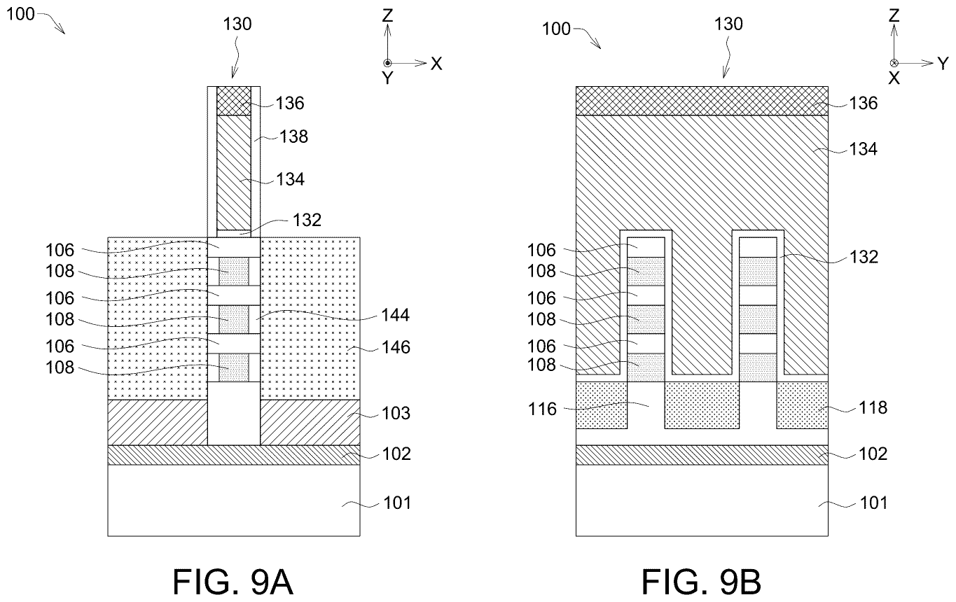

FIGS. 9A-14A are cross-sectional views of various stages of manufacturing the semiconductor device 100 taken along cross-section A-A of FIG. 6, in accordance with some embodiments. FIGS. 9B-14B are cross-sectional views of various stages of manufacturing the semiconductor device 100 taken along cross-section B-B of FIG. 6, in accordance with some embodiments. As shown in FIGS. 9A and 9B, epitaxial S/D features 146 are formed in the source/drain (S/D) regions. The epitaxial S/D features 146 may be made of one or more layers of Si, SiP, SiC and SiCP for n-channel FETs or Si, SiGe, Ge for p-channel FETs. For p-channel FETs, p-type dopants, such as boron (B), may also be included in the epitaxial S/D features 146. The epitaxial S/D features 146 may be formed by an epitaxial growth method using CVD, ALD or MBE. The epitaxial S/D features 146 may grow both vertically and horizontally to form facets, which may correspond to crystalline planes of the material used for the substrate 101. In some cases, the epitaxial S/D features 146 of a fin structure may grow and merge with the epitaxial S/D features 146 of the neighboring fin structures.

In some embodiments, prior to formation of the S/D epitaxial features 146, a S/D pre-clean process may be performed to remove a native oxide layer that is formed on the first semiconductor layers 106 and the dielectric spacers 144. The S/D pre-clean process may be an inert gas sputtering process (e.g., argon sputter) or a plasma-based cleaning process. In one embodiment, the S/D pre-clean process is a SiCoNi process which uses a remote plasma source to generate ammonium fluoride (NH₄F) etchant species from nitrogen trifluoride (NF₃) and ammonia (NH₃) to minimize the damage to the semiconductor device 100.

In one example shown in FIG. 9A, one of a pair of epitaxial S/D features 146 disposed on one side of the sacrificial gate structure 130 is designated as a source feature/terminal, and the other of the pair of epitaxial S/D features 146 disposed on the other side of the sacrificial gate structure 130 is designated as a drain feature/terminal. The source feature/terminal and the drain feature/terminal are connected by the channel layers (e.g., the first semiconductor layers 106). The epitaxial S/D features 146 are in contact with the first semiconductor layer 106 under the sacrificial gate structure 130. In some cases, the epitaxial S/D features 146 may grow pass the topmost semiconductor channel, i.e., the first semiconductor layer 106 under the sacrificial gate structure 130, to be in contact with the gate spacers 138. The second semiconductor layer 108 under the sacrificial gate structure 130 are separated from the epitaxial S/D features 146 by the dielectric spacers 144.

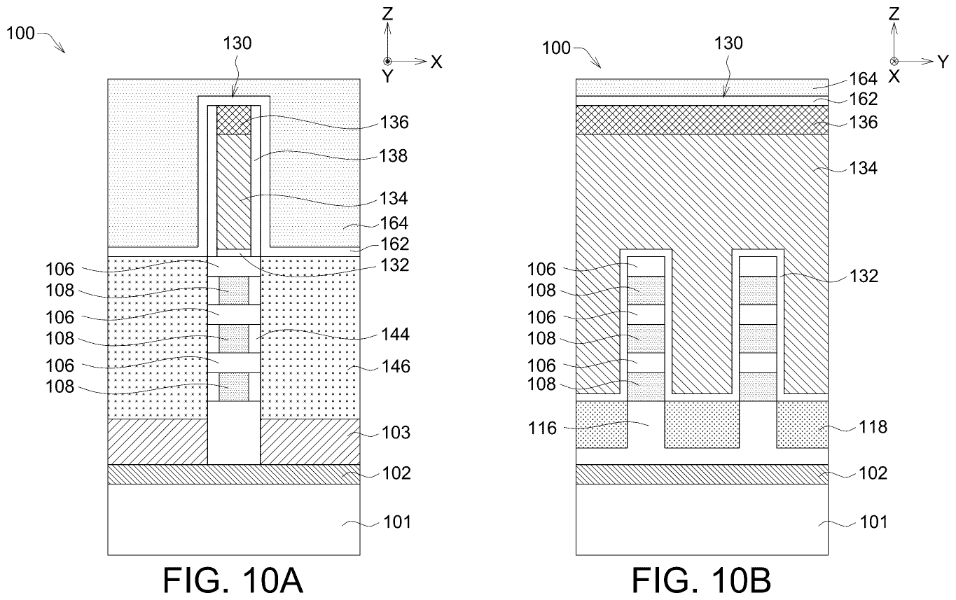

In FIGS. 10A-10B, a contact etch stop layer (CESL) 162 is conformally formed on the exposed surfaces of the semiconductor device 100. The CESL 162 covers the sidewalls of the sacrificial gate structure 130, the insulating material 118, the epitaxial S/D features 146, and the exposed surface of the stack of semiconductor layers 104. The CESL 162 may include an oxygen-containing material or a nitrogen-containing material, such as silicon nitride, silicon carbon nitride, silicon oxynitride, carbon nitride, silicon oxide, silicon carbon oxide, or the like, or a combination thereof, and may be formed by CVD, PECVD, ALD, or any suitable deposition technique. Next, a first interlayer dielectric (ILD) layer 164 is formed on the CESL 162 over the semiconductor device 100. The materials for the first ILD layer 164 may include compounds comprising Si, O, C, and/or H, such as silicon oxide, TEOS oxide, SiCOH and SiOC. Organic materials, such as polymers, may also be used for the first ILD layer 164. The first ILD layer 164 may be deposited by a PECVD process or other suitable deposition technique. In some embodiments, after formation of the first ILD layer 164, the semiconductor device 100 may be subject to a thermal process to anneal the first ILD layer 164.

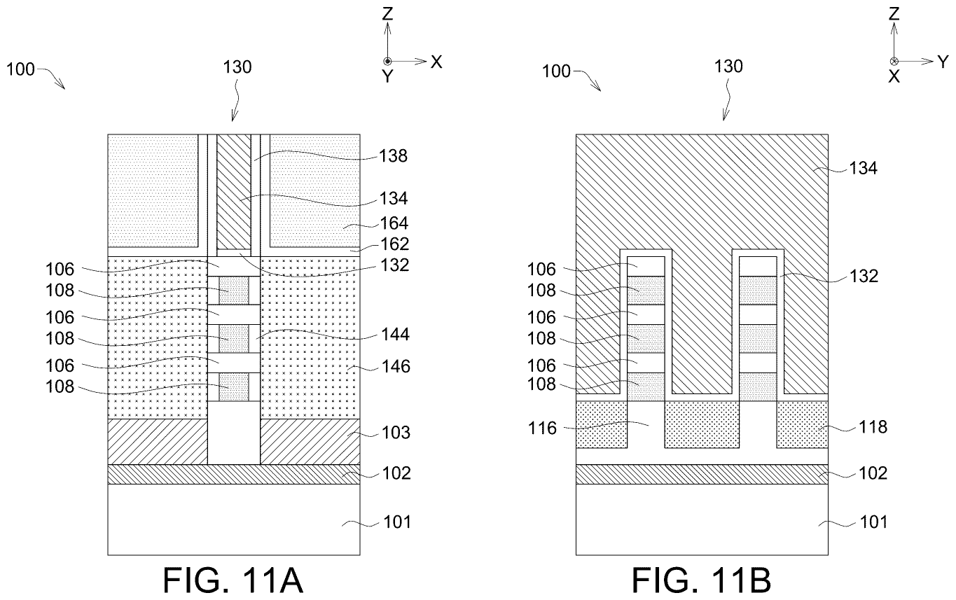

In FIGS. 11A-11B, after the first ILD layer 164 is formed, a planarization operation, such as CMP, is performed on the semiconductor device 100 until the sacrificial gate electrode layer 134 is exposed.

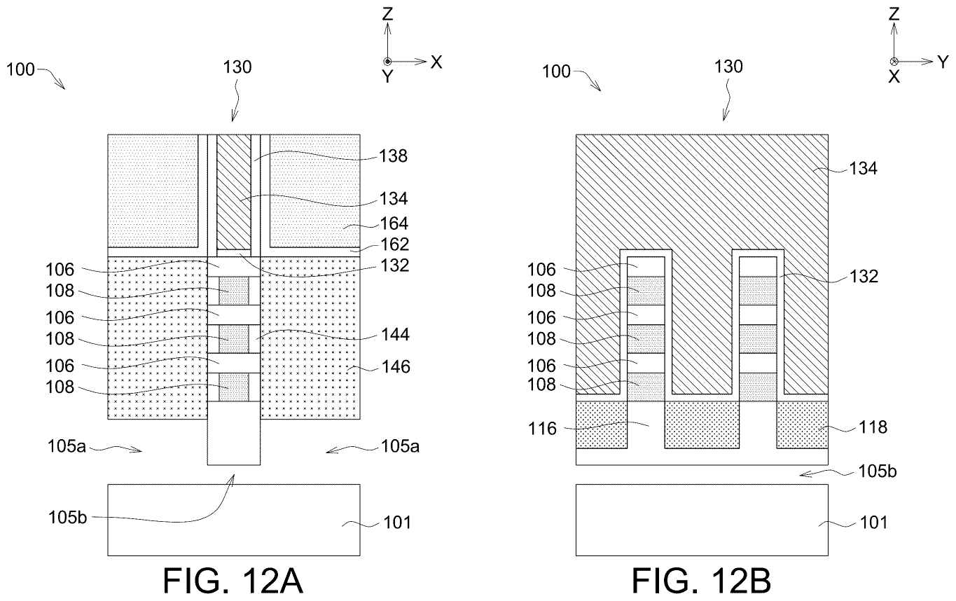

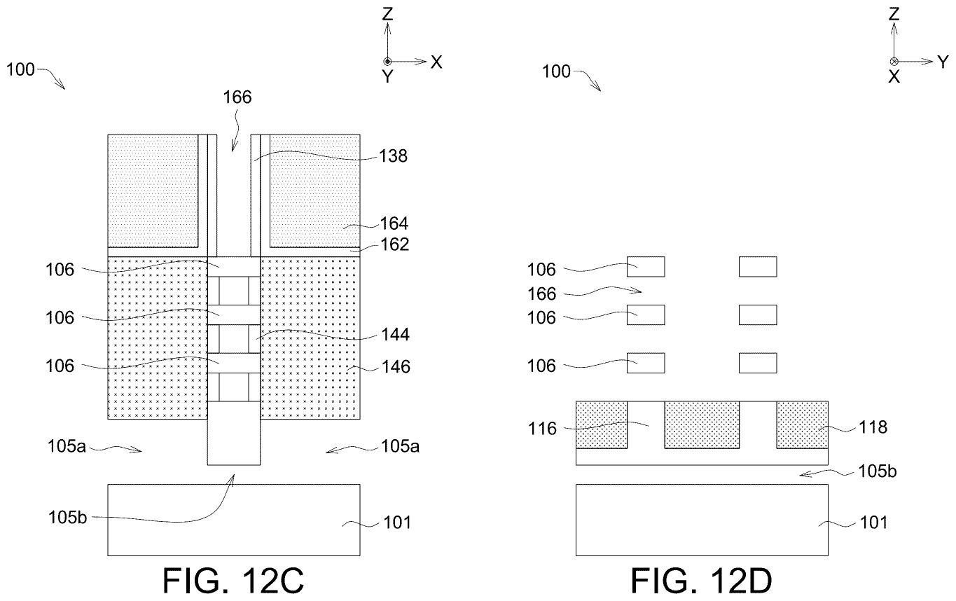

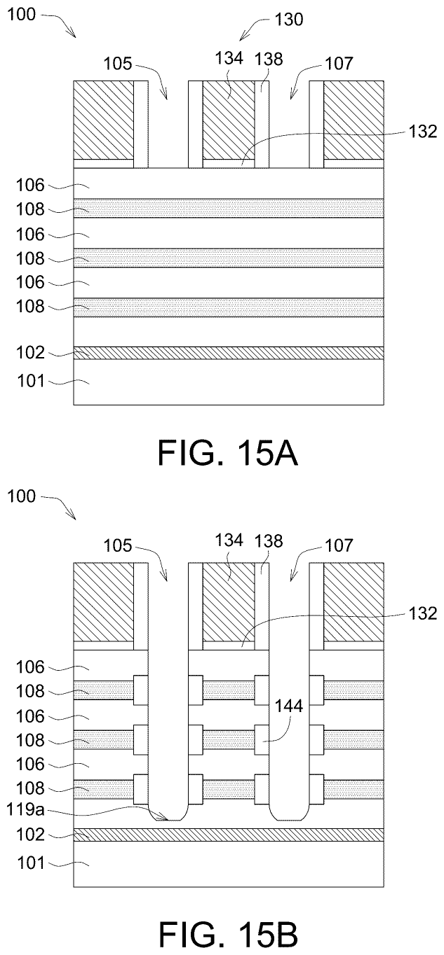

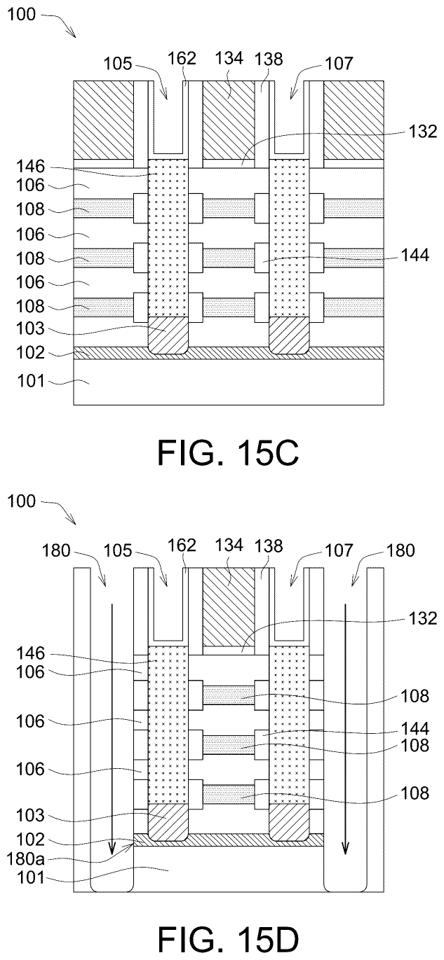

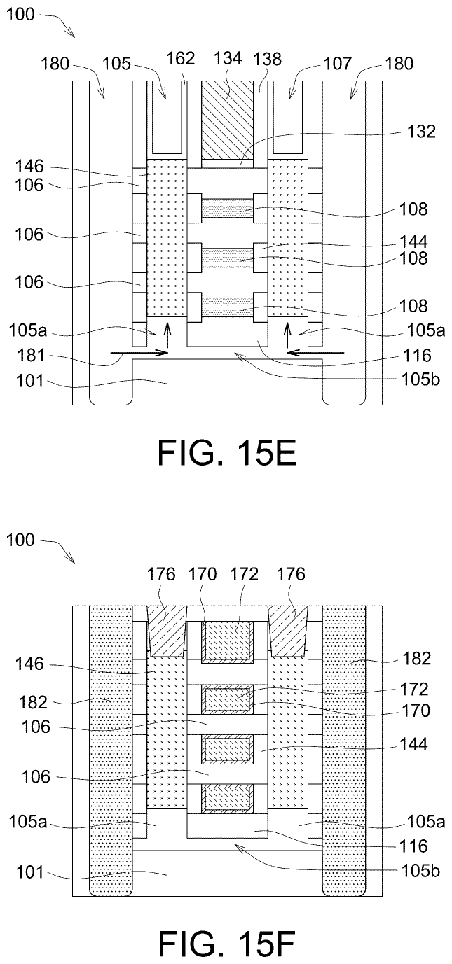

In FIGS. 12A-12B, the sacrificial layer 102 and/or the elevated layer 103 can be removed together. In another embodiment, the sacrificial layer 102 and the elevated layer 103 can be removed separately. The method of removing the sacrificial layer 102 can be performed in a cut-on-poly-oxide-definition-edge (CPODE) process. The CPODE process can form a vertically extending trench 180 in the area surrounding the epitaxial source/drain feature 146, with one end (lower end) of the trench 180 extending to the substrate 101, and the sacrificial layer 102 is exposed on the sidewalls of the trench 180, as shown in FIG. 15D.

In FIGS. 12C-12D, the sacrificial gate structure 130 and the second semiconductor layers 108 are removed. In another embodiment, the sacrificial gate structure 130 and the second semiconductor layers 108 with different materials can be removed separately. The removal of the sacrificial gate structure 130 and the semiconductor layers 108 forms an opening 166 between gate spacers 138 and between first semiconductor layers 106. The ILD layer 164 protects the S/D epitaxial features 146 during the removal processes. The sacrificial gate structure 130 can be removed using plasma dry etching and/or wet etching. The sacrificial gate electrode layer 134 may be first removed by any suitable process, such as dry etch, wet etch, or a combination thereof, followed by the removal of the sacrificial gate dielectric layer 132, which may also be performed by any suitable process, such as dry etch, wet etch, or a combination thereof. In some embodiments, a wet etchant such as a tetramethylammonium hydroxide (TMAH) solution can be used to selectively remove the sacrificial gate electrode layer 134 but not the gate spacers 138, the dielectric material 125, the ILD layer 164, and the CESL 162.

Portions of the second semiconductor layers 108 may be removed using a selective wet etching process. In cases where the second semiconductor layers 108 and the sacrificial layer 102/the elevated layer 103 are made of SiGe and the first semiconductor layers 106 are made of Si, the chemistry used in the selective wet etching process removes the SiGe while not substantially affecting Si, the dielectric materials of the gate spacers 138, and the dielectric spacers 144. In one embodiment, the second semiconductor layers 108 and the sacrificial layer 102/the elevated layer 103 can be removed using a wet etchant such as, but not limited to, hydrofluoric (HF), nitric acid (HNO₃), hydrochloric acid (HCl), phosphoric acid (H₃PO₄), a dry etchant such as fluorine-based (e.g., F₂) or chlorine-based gas (e.g., Cl₂), or any suitable isotropic etchants.

When the sacrificial layer 102 and the elevated layer 103 are removed, a gap 105a is formed between the epitaxial source/drain feature 146 and the substrate 101. In the same way, an internal connection channel 105b can also be formed below the nanostructure channel (i.e., below the well portion 116) to isolate leakage current from flowing to the substrate 101 via the epitaxial source/drain feature 146 and/or the well portion 116. Relative to other dielectric materials (such as silicon dioxide), the dielectric constant of air in the gap 105a is close to 1, which is lower than silicon dioxide. By using air with a low dielectric coefficient in the semiconductor device 100 to replace traditional insulating materials such as silicon dioxide, the leakage current of the semiconductor device 100 can be reduced, and the capacitance effect between wires, mesa parasitic capacitance or heat generation can be reduced.

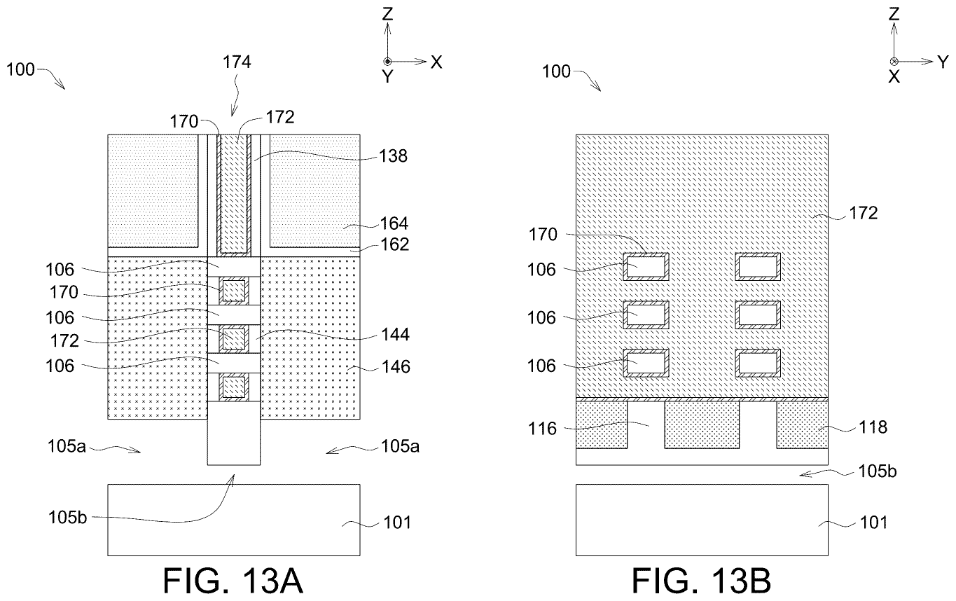

In FIGS. 13A-13B, after the formation of the nanostructure channels (i.e., the exposed first semiconductor layers 106), a gate dielectric layer 170 is formed to surround the first semiconductor layers 106, and a gate electrode layer 172 is formed on the gate dielectric layer 170. The gate dielectric layer 170 and the gate electrode layer 172 may be collectively referred to as a gate structure 174. In some embodiments, an interfacial layer (IL) (not shown) is formed between the gate dielectric layer 170 and the exposed surfaces of the first semiconductor layers 106. In such cases, the IL may also form on the well portion 116 of the substrate 101. The IL may include or be made of an oxygen-containing material or a silicon-containing material, such as silicon oxide, silicon oxynitride, oxynitride, hafnium silicate, etc. The IL may be formed by CVD, ALD, a clean process, or any suitable process. In some embodiments, the gate dielectric layer 170 includes one or more layers of a dielectric material, such as silicon oxide, silicon nitride, or high-K dielectric material, other suitable dielectric material, and/or combinations thereof. Examples of high-k dielectric material include HfO₂, HfSiO, HfSiON, HfTaO, HfSiO, HfZrO, zirconium oxide, aluminum oxide, titanium oxide, hafnium dioxide-alumina (HfO₂—Al₂O₃) alloy, other suitable high-k dielectric materials, and/or combinations thereof. The gate dielectric layer 170 may be formed by CVD, ALD or any suitable deposition technique.

The gate electrode layer 172 may include one or more layers of conductive material, such as polysilicon, aluminum, copper, titanium, tantalum, tungsten, cobalt, molybdenum, tantalum nitride, nickel silicide, cobalt silicide, TIN, WN, TiAl, TiAIN, TaCN, TaC, TaSiN, metal alloys, other suitable materials, and/or any combinations thereof. The gate electrode layer 172 may be formed by CVD, ALD, electro-plating, or other suitable deposition technique. The gate electrode layer 172 may be also deposited over the upper surface of the first ILD layer 164. The gate dielectric layer 170 and the gate electrode layer 172 formed over the first ILD layer 164 are then removed by using, for example, CMP, until the top surface of the first ILD layer 164 is exposed.

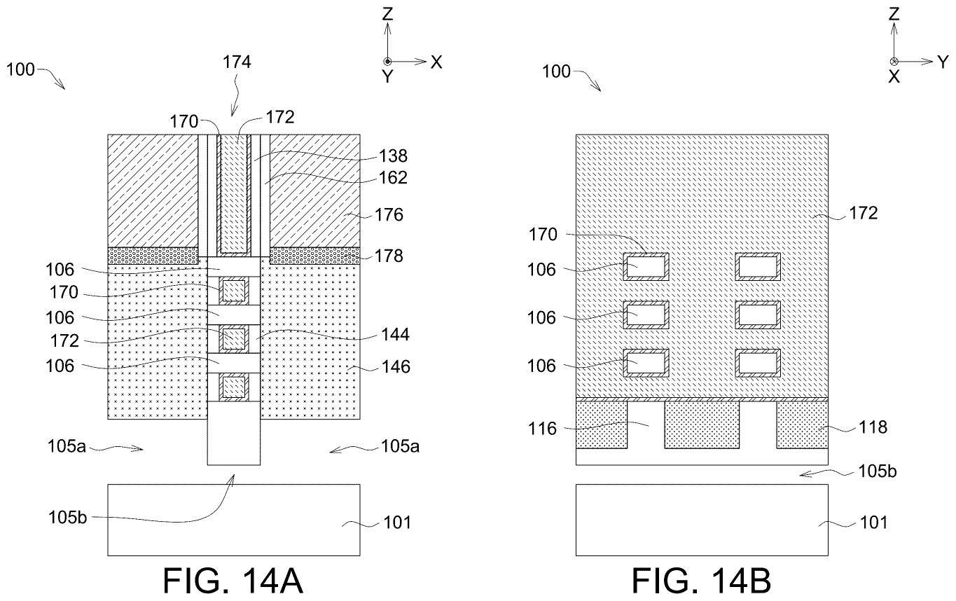

In FIGS. 14A-14B, source/drain (S/D) contacts 176 are formed in the first ILD layer 164. Prior to forming the S/D contacts 176, contact openings are formed in the first ILD layer 164 to expose the epitaxial S/D features 146. Suitable photolithographic and etching techniques are used to form the contact openings through various layers, including the first ILD layer 164 and the CESL 162 to expose the epitaxial S/D features 146. In some embodiments, the upper portions of the epitaxial S/D features 146 are etched.

After the formation of the contact openings, a silicide layer 178 is formed on the epitaxial S/D features 146. The silicide layer 178 conductively couples the epitaxial S/D features 146 to the subsequently formed S/D contacts 176. The silicide layer 178 may be formed by depositing a metal source layer over the epitaxial S/D features 146 and performing a rapid thermal annealing process. During the rapid annealing process, the portion of the metal source layer over the epitaxial S/D features 146 reacts with silicon in the epitaxial S/D features 146 to form the silicide layer 178. Unreacted portion of the metal source layer is then removed. In some embodiments, the silicide layer 178 is made of a metal or metal alloy silicide, and the metal includes a noble metal, a refractory metal, a rare earth metal, alloys thereof, or combinations thereof. Next, a conductive material is formed in the contact openings and form the S/D contacts 176. The conductive material may be made of a material including one or more of Ru, Mo, Co, Ni. W, Ti, Ta, Cu, Al, TiN and TaN. While not shown, a barrier layer (e.g., TiN, TaN, or the like) may be formed on sidewalls of the contact openings prior to forming the S/D contacts 176. Then, a planarization process, such as CMP, is performed to remove excess deposition of the contact material and expose the top surface of the gate electrode layer 172.

It is understood that the semiconductor device 100 may undergo further complementary metal oxide semiconductor (CMOS) and/or back-end-of-line (BEOL) processes to form various features such as transistors, contacts/vias, interconnect metal layers, dielectric layers, passivation layers, etc. The semiconductor device 100 may also include backside contacts (not shown) on the backside of the substrate 101 so that either source or drain of the epitaxial S/D features 146 is connected to a backside power rail (e.g., positive voltage VDD or negative voltage VSS) through the backside contacts.

Referring to FIGS. 15A to 15F, schematic diagrams of a method of removing the sacrificial layer 102 according to an embodiment of the present disclosure are illustrated. In FIG. 15A, according to FIG. 5, at least one gate structure 130 are formed above the fin structure 112, and the fin structure 112 exposed between two adjacent sacrificial gates structures 130 define the source/drain regions 105, 107 of the semiconductor device structure 100. In FIG. 15B, the portion of the fin structure 112 not covered by the sacrificial gate structure 130 is removed, leaving only the bottom portion 119 of the source/drain regions 105 and 107, so that the source/drain regions 105 and 107 are not connected to the sacrificial layer 102. After the etching process of FIGS. 8A and 8B and the dielectric spacers 144 are completed, the bottom portions 119 of the source/drain regions 105 and 107 are removed.

In FIG. 15C, according to FIGS. 8C and 8D, the sacrificial layer 102 is exposed in the source/drain regions 105 and 107, and the elevated layer 103 of the same material as the sacrificial layer 102 is further deposited or refilled above the sacrificial layer 102. Next, the epitaxial S/D features 146 are formed over the sacrificial layer 102 and/or the elevated layer 103. In FIG. 15D, a vertically extending trench 180 is formed around the epitaxial source/drain feature 146. The trench 180 extends into the substrate 101 to expose the sacrificial layer 102 on the sidewall 180a of the trench 180. In FIG. 15E, a wet etchant 181 is passed into the vertically extending trench 180, and a wet etching process is used to remove the sacrificial layer 102 and the elevated layer 103 to form a gap 105a between the epitaxial source/drain feature 146 and the substrate 101. At the same time, the wet etchant 181 can further etch the sacrificial layer 102 below the nanostructure channel (i.e., below the well portion 116) to form an internal connection channel 105b between the well portion 116 and the substrate 101. In one embodiment, the internal connection channel 105b can connect with two adjacent gaps 105a or more gaps 105a. In FIG. 15F, an insulating material is filled into the vertically extending trench 180 to fill with filler 182 in the trench 180. The filler 182 may include a silicon-containing material, such as silicon oxide, silicon nitride, silicon oxynitride, etc. The filler 182, such as a cut metal gate (CMG) trench filler or a cut-on-poly-oxide-definition-edge (CPODE) filler, may be deposited using CVD, PVD, ALD, or other suitable methods and formed in the trench 180.

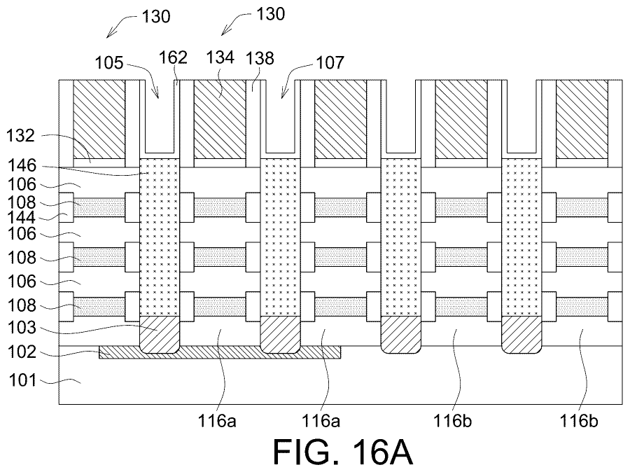

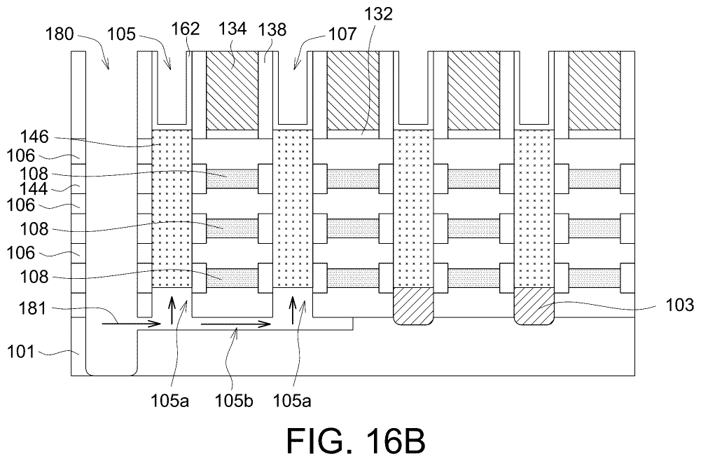

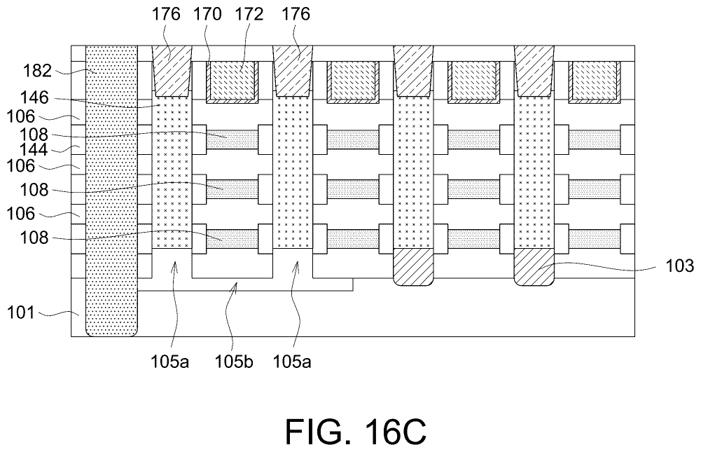

Referring to FIGS. 16A to 16C, which illustrate that the wet etchant 181 can further etch the sacrificial layer 102 below one part of the nanostructure channels (i.e., below the well portion 116a on the left side) to form an internal connection channel 105b between two adjacent gaps 105a. In addition, there is no sacrificial layer formed under another part of the nanostructure channels (for example, the two well portions 116b on the right side), so that there is still an elevated layer 103 or other insulating material between the epitaxial source/drain feature 146 and the substrate 101. In another embodiment, the wet etchant 181 can also enter the other gaps 105s under two or more epitaxial source/drain feature 146 along the internal connection channel 105b to form a longer internal connection channel 105b.

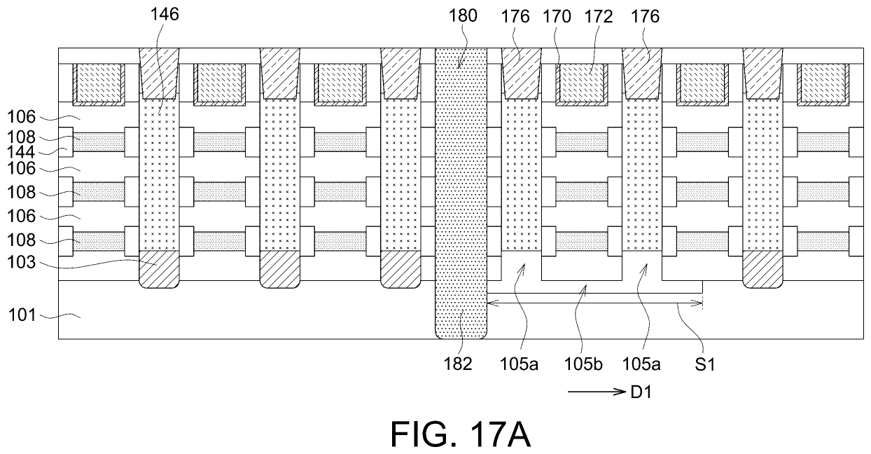

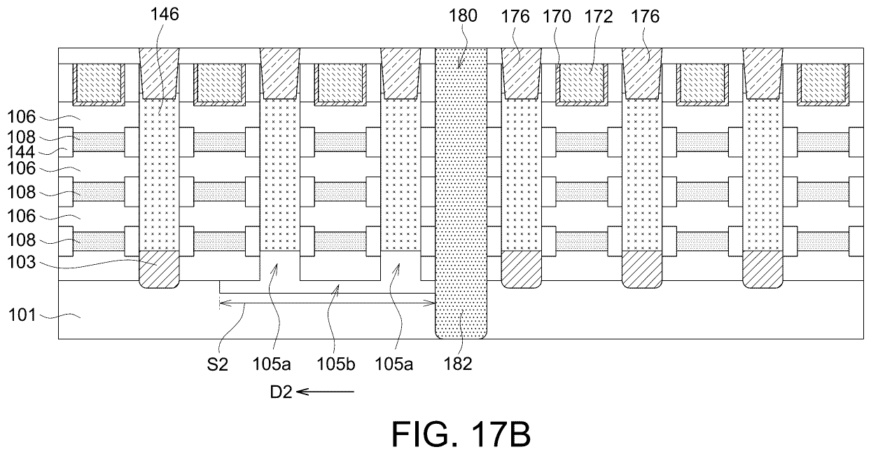

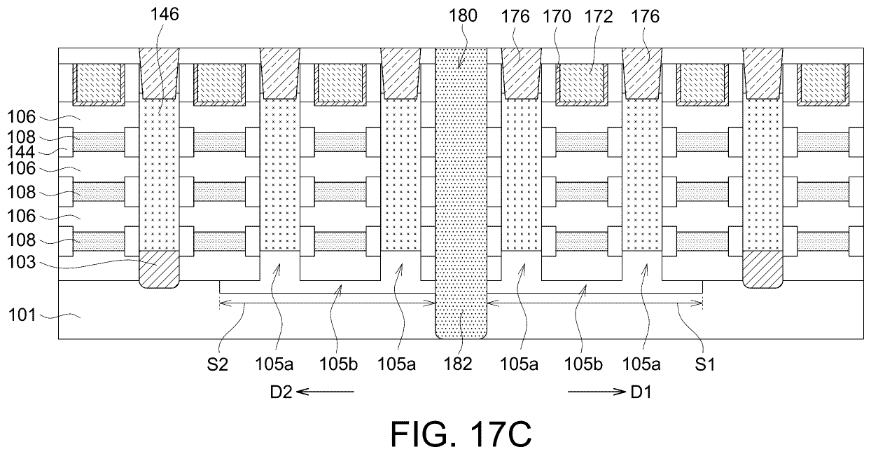

Refer to FIGS. 17A to 17C. The internal connection channel 105b may extend from one side of the vertically extending trench 180 to the first direction D1 by a first distance S1, or from another side of the vertically extending groove 180 to the second direction D1 by a second distance S2. The first direction D1 and the second direction D2 are two opposite directions, and the first direction D1 and the second direction D2 are substantially perpendicular to the extending direction of the trench 180. In another embodiment, the internal connection channel 105b may also extend from both sides of the vertically extending trench 180 to the opposite first direction D1 and the second direction D2.

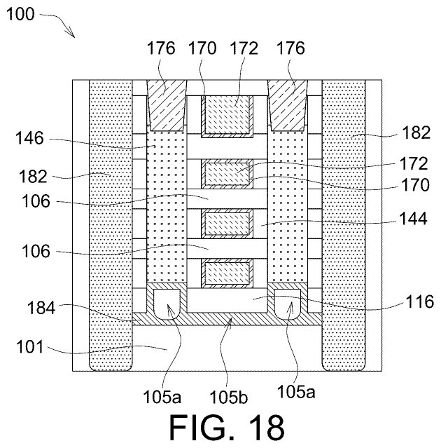

Referring to FIG. 18, which illustrates a semiconductor device similar to the semiconductor device of FIG. 15F. The difference is that in FIG. 18, a wet etching process is used to remove the sacrificial layer 102 and the elevated layer 103 to form a gap 105a between the epitaxial source/drain feature 146 and the substrate 101, then an insulating layer 184 can be further filled in the gap 105a and the internal connection channel 105b, and the insulating layer 184 covers the upper surface of the substrate 101, the bottom surface of the epitaxial S/D feature 146 and the bottom surface and sidewalls of the well portion 116 and may enclose air therein. The insulating layer 184 may include materials such as silicon oxide, silicon nitride, silicon oxynitride, etc., and may be deposited using CVD, PVD, ALD, or other suitable methods.

The present disclosure relates to a semiconductor device and a manufacturing method thereof, in which a bottom portion of the source/drain regions covering the sacrificial layer is removed, such as by etching. Then, the sacrificial layer is exposed in the source/drain regions and a wet etching process is used to remove the sacrificial layer to form a gap between the epitaxial source/drain feature and the substrate. At the same time, the wet etchant can further etch the sacrificial layer below the well portion to form an internal connection channel between the well portion and the substrate. Since the dielectric constant of air in the gap is lower than silicon dioxide, the leakage current of the semiconductor device can be reduced, and the capacitance effect between wires, mesa parasitic capacitance or heat generation can be reduced.

According to some embodiments of the present disclosure, a method of manufacturing a semiconductor device is provided. A sacrificial layer is formed on a substrate. A fin structure having a plurality of first semiconductor layers and a plurality of second semiconductor layers alternately stacked is formed, and the fin structure covers the sacrificial layer. Edge portions of the second semiconductor layers is removed to form a plurality of cavities between the first semiconductor layers. A dielectric spacer is formed on sidewalls of the second semiconductor layers and fills the cavities. A bottom portion of the fin structure that covers the sacrificial layer is etched to expose the sacrificial layer. An epitaxial source/drain feature is formed such that a side surface of the epitaxial source/drain feature contacts the first semiconductor layers and the dielectric spacers, and a bottom surface of the epitaxial source/drain feature contact the sacrificial layer. The sacrificial layer is removed to form a gap between the epitaxial source/drain feature and the substrate.

According to some embodiments of the present disclosure, a method of manufacturing a semiconductor device is provided. A sacrificial layer and a fin structure are formed on a substrate, the fin structure comprises a plurality of first semiconductor layers and a plurality of second semiconductor layers that are alternately stacked, wherein the fin structure covers the sacrificial layer. A sacrificial gate structure is formed over a portion of the fin structure. The first semiconductor layers and the second semiconductor layers not covered by the sacrificial gate structure in a source/drain region of the fin structure are removed. The edge portions of the second semiconductor layers are removed. A plurality of dielectric spacers is formed on sidewalls of the second semiconductor layers and between the first semiconductor layers. A bottom portion of the source/drain region is etched to expose the sacrificial layer. An epitaxial source/drain feature is formed in the source/drain region, wherein a bottom surface of the epitaxial source/drain feature contacts the sacrificial layer. The sacrificial layer is removed to form a gap between the epitaxial source/drain feature and the substrate. Portions of the sacrificial gate structure are removed to expose the first semiconductor layers and the second semiconductor layers. The second semiconductor layers is removed. A gate dielectric layer is formed to surround an exposed surface of each of the first semiconductor layers. a gate electrode layer is formed on the gate dielectric layer.

According to some embodiments of the present disclosure, a method of manufacturing a semiconductor device is provided. A sacrificial layer is formed on a substrate. A first source/drain epitaxial feature is formed above the sacrificial layer. a second source/drain epitaxial feature is formed above the sacrificial layer. Two or more semiconductor layers are formed between the first source/drain epitaxial feature and the second source/drain epitaxial feature. The sacrificial layer is removed to form a first gap between the first epitaxial source/drain feature and the substrate and a second gap between the second epitaxial source/drain feature and the substrate. A gate dielectric layer is formed to surround an exposed surface of each of the two or more semiconductor layers. A gate electrode layer is formed on the gate dielectric layer.

According to some embodiments of the present disclosure, a semiconductor device including a substrate, a first source/drain epitaxial feature, a second source/drain epitaxial feature and two or more semiconductor layers is provided. The first source/drain epitaxial feature is disposed in a first source/drain region. The second source/drain epitaxial feature disposed in a second source/drain region. The semiconductor layers are disposed between the first source/drain epitaxial feature and the second source/drain epitaxial feature. A bottom portion of the first source/drain region has a first gap between the first source/drain epitaxial feature and the substrate, and a bottom portion of the second source/drain region has a second gap between the first source/drain epitaxial feature and the substrate.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing a semiconductor device, comprising:
forming a sacrificial layer on a substrate;
forming a fin structure having a plurality of first semiconductor layers and a plurality of second semiconductor layers alternately stacked, the fin structure covering the sacrificial layer;
removing edge portions of the second semiconductor layers to form a plurality of cavities between the first semiconductor layers;
forming a dielectric spacer on sidewalls of the second semiconductor layers and filling the cavities;
etching a bottom portion of the fin structure that covers the sacrificial layer to expose the sacrificial layer;
forming an epitaxial source/drain feature such that a side surface of the epitaxial source/drain feature contacts the first semiconductor layers and the dielectric spacers, and a bottom surface of the epitaxial source/drain feature contact the sacrificial layer; and
removing the sacrificial layer to form a gap between the epitaxial source/drain feature and the substrate.

2. The method of claim 1, further comprising forming an elevated layer on the sacrificial layer before forming the epitaxial source/drain feature.

3. The method of claim 2, wherein a material of the elevated layer is the same as materials of the sacrificial layer and the second semiconductor layer, and the elevated layer, the sacrificial layer and the second semiconductor layer are removed in a same process.

4. The method of claim 1, wherein removing the sacrificial layer comprises:
etching the first and second semiconductor layers to form a vertically extending trench in a region surrounding the epitaxial source/drain feature that extends into the substrate to expose the sacrificial layer on a sidewall of the trench; and
passing an etchant into the trench to remove the sacrificial layer.

5. The method of claim 4, wherein the etchant enters below the fin structure along the gap and etches the sacrificial layer below the fin structure to form an internal connection channel.

6. The method of claim 5, wherein the internal connection channel is located between two adjacent gaps.

7. The method of claim 4, further comprising filling an insulating material in the vertically extending trench to isolate the gap after removing the sacrificial layer.

8. A method of manufacturing a semiconductor device, comprising:
forming a sacrificial layer and a fin structure on a substrate, the fin structure comprising a plurality of first semiconductor layers and a plurality of second semiconductor layers that are alternately stacked, wherein the fin structure covers the sacrificial layer;
forming a sacrificial gate structure over a portion of the fin structure;
removing the first semiconductor layers and the second semiconductor layers not covered by the sacrificial gate structure in a source/drain region of the fin structure;
removing edge portions of the second semiconductor layers;
forming a plurality of dielectric spacers on sidewalls of the second semiconductor layers and between the first semiconductor layers;
etching a bottom portion of the source/drain region to expose the sacrificial layer;
forming an epitaxial source/drain feature in the source/drain region, wherein a bottom surface of the epitaxial source/drain feature contacts the sacrificial layer;
removing the sacrificial layer to form a gap between the epitaxial source/drain feature and the substrate;
removing portions of the sacrificial gate structure to expose the first semiconductor layers and the second semiconductor layers;
removing the second semiconductor layers;
forming a gate dielectric layer to surround an exposed surface of each of the first semiconductor layers; and
forming a gate electrode layer on the gate dielectric layer.

9. The method of claim 8, further comprising forming an elevated layer on the sacrificial layer before forming the epitaxial source/drain feature.

10. The method of claim 8, wherein a material of the elevated layer is the same as materials of the sacrificial layer and the second semiconductor layer, and the elevated layer, the sacrificial layer and the second semiconductor layer are removed in a same process.

11. The method of claim 8, wherein removing the sacrificial layer comprises:
etching the first and second semiconductor layers to form a vertically extending trench in a region surrounding the epitaxial source/drain feature that extends into the substrate to expose the sacrificial layer on a sidewall of the trench; and
passing an etchant into the trench to remove the sacrificial layer.

12. The method of claim 11, further comprising filling an insulating material in the vertically extending trench to isolate the gap after removing the sacrificial layer.

13. The method of claim 11, wherein the etchant enters below the fin structure along the gap and etches the sacrificial layer below the fin structure to form an internal connection channel.

14. A semiconductor device, comprising:
a substrate;
a first source/drain epitaxial feature disposed in a first source/drain region;
a second source/drain epitaxial feature disposed in a second source/drain region; and
two or more semiconductor layers disposed between the first source/drain epitaxial feature and the second source/drain epitaxial feature;
wherein a bottom portion of the first source/drain region has a first gap between the first source/drain epitaxial feature and the substrate, and a bottom portion of the second source/drain region has a second gap between the first source/drain epitaxial feature and the substrate.

15. The semiconductor device of claim 14, further comprising a first vertically extending trench extending into the substrate to expose the first gap on one side of the first vertically extending trench and a filler disposed in the first vertically extending trench to seal the first gap.

16. The semiconductor device of claim 15, further comprising a second vertically extending trench extending into the substrate to expose the second gap on one side of the second vertically extending trench and a filler disposed in the second vertically extending trench to seal the second gap.

17. The semiconductor device of claim 16, further comprising an internal connection channel located between the first gap and the second gap.

18. The semiconductor device of claim 16, further comprising an insulating layer filled in the first gap and the second gap.

19. The semiconductor device of claim 16, further comprising an internal connection channel extending from both sides of the second vertically extending trench.

20. The semiconductor device of claim 15, further comprising an internal connection channel extending from both sides of the first vertically extending trench.
